(19) United States
(12) Patent Application Publication
(10) Pub. No.: US 2024/0234132 A1
(43) Pub. Date: Jul. 11, 2024

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: KOKUSAI ELECTRIC CORPORATION, Tokyo (JP)

(72) Inventors: Yusuke TERUI, Toyama-shi (JP); Yuki YAMAKADO, Toyama-shi (JP); Yoshitomo HASHIMOTO, Toyama-shi (JP); Masanori NAKAYAMA, Toyama-shi (JP)

(73) Assignee: KOKUSAI ELECTRIC CORPORATION, Tokyo (JP)

(21) Appl. No.: 18/614,067

(22) Filed: Mar. 22, 2024

Related U.S. Application Data
(63) Continuation of application No. PCT/JP22/31498, filed on Aug. 22, 2022.

(30) Foreign Application Priority Data
Dec. 24, 2021 (JP) 2021-211201

(51) Int. Cl. H01L 21/02; C23C 16/30; C23C 16/46; C23C 16/50; C23C 16/52; C23C 16/56; H01J 37/32

(52) U.S. Cl. CPC H01L 21/0234; C23C 16/30; C23C 16/46; C23C 16/50; C23C 16/52; C23C 16/56; H01J 37/32926; H01L 21/02126; H01L 21/0214; H01J 2237/338

(57) ABSTRACT

A technique includes (a) providing a substrate on which a first film containing at least one selected from the group of a combination of C—H bonds and Si—C bonds and a combination of N—H bonds and Si—N bonds is formed, (b) modifying the first film into a second film by performing heat processing to the first film at a processing temperature higher than a processing temperature at which the first film is formed, and (c) modifying the second film into a third film by performing plasma processing to the second film so that a ratio of Si—C bonds to C—H bonds in the third film is made larger than a ratio of Si—C bonds to C—H bonds in the first film, or a ratio of Si—N bonds to N—H bonds in the third film is made larger than a ratio of Si—N bonds to N—H bonds in the first film.

### REFERENCE TO RELATED APPLICATIONS

This application is a Bypass Continuation Application of PCT International Application No. PCT/JP2022/031498, filed on Aug. 22, 2022 and designating the United States, the international application being based upon and claiming the benefit of priority from Japanese Patent Application No. 2021-211201, filed on Dec. 24, 2021, the entire content of which is incorporated herein by reference.

### TECHNICAL FIELD

The present disclosure relates to a method of processing a substrate, a method of manufacturing a semiconductor device, a recording medium, and a substrate processing apparatus.

### BACKGROUND OF THE INVENTION

As a process of manufacturing a semiconductor device, a process of forming a film on a substrate is sometimes performed.

### SUMMARY OF THE INVENTION

Some embodiments of the present disclosure provide a technique capable of improving the properties of a film formed on a substrate.

According to one embodiment of the present disclosure, there is provided a technique that includes (a) providing a substrate on which a first film containing at least one selected from the group of a combination of C—H bonds and Si—C bonds and a combination of N—H bonds and Si—N bonds is formed; (b) modifying the first film into a second film by performing heat processing to the first film at a processing temperature higher than a processing temperature at which the first film is formed; and (c) modifying the second film into a third film by performing plasma processing to the second film so that a ratio of Si—C bonds to C—H bonds in the third film is made larger than a ratio of Si—C bonds to C—H bonds in the first film, or a ratio of Si—N bonds to N—H bonds in the third film is made larger than a ratio of Si—N bonds to N—H bonds in the first film.

### BRIEF DESCRIPTION OF DRAWINGS

The accompanying drawings, which are incorporated in and constitute a part of the specification, illustrate embodiments of the present disclosure.

FIG. 1 is a sectional view schematically showing a configuration example of a substrate-processing unit suitably used in one embodiment of the present disclosure.

FIG. 2 is a schematic configuration diagram of a controller of the substrate-processing unit suitably used in one embodiment of the present disclosure, in which the control system of the controller is shown in a block diagram.

FIG. 3 is a side sectional view schematically showing a configuration example of a film-forming apparatus suitably used in one embodiment of the present disclosure.

FIG. 4 is a side sectional view schematically showing a configuration example of an annealing apparatus suitably used in one embodiment of the present disclosure.

FIG. 5 is a side sectional view schematically showing a configuration example of a plasma-processing apparatus suitably used in one embodiment of the present disclosure.

FIG. 6 is a flowchart showing a substrate-processing process according to one embodiment of the present disclosure.

FIG. 7 is a diagram illustrating a processing sequence according to one embodiment of the present disclosure.

FIG. 8 is a diagram showing measurement results in examples.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### One Embodiment of the Present Disclosure

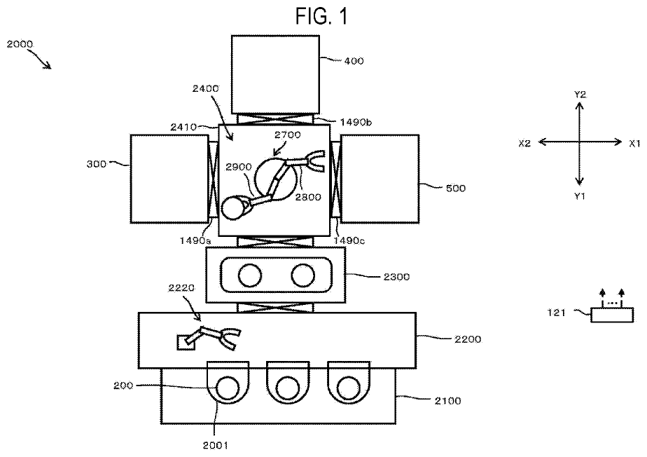

Hereinafter, one embodiment of the present disclosure will be described mainly with reference to FIGS. 1 to 7. The drawings used in the following description are all schematic, and the dimensional relationship of each element, the ratio of each element, etc. shown in the drawings do not necessarily match the real ones. Moreover, the dimensional relationship of each element, the ratio of each element, etc. do not necessarily match between a plurality of drawings.

The substrate-processing unit 2000 exemplified in the present embodiment is used in a process of manufacturing a semiconductor device, and is configured to perform predetermined processing to a substrate to be processed. Examples of the substrate to be processed include a semiconductor wafer substrate (hereinafter simply referred to as “wafer”) on which semiconductor integrated circuit devices (semiconductor devices) are fabricated. The term “wafer” used herein may refer to a wafer itself or a stacked body (aggregate) of a wafer and a predetermined layer or film formed on the surface of the wafer (i.e., a wafer including a predetermined layer or film formed on a surface thereof). Further, the phrase “a surface of a wafer” used herein may refer to a surface (exposed surface) of a wafer itself or a surface of a predetermined layer or the like formed on a wafer, i.e., an outermost surface of a wafer as a stacked body. The term “substrate” used herein is synonymous with the term “wafer.” In addition, the processing performed to a wafer includes, for example, transfer processing, pressurization (depressurization) processing, heat processing, film formation processing, modification processing, diffusion processing, reflow or annealing for carrier activation and planarization after ion implantation, and the like.

### (1) Configuration of Substrate-Processing Unit

First, a configuration example of a substrate-processing unit 2000 as a substrate-processing apparatus will be described.

As shown in FIG. 1, the substrate-processing unit 2000 is a so-called cluster type apparatus that processes a wafer 200 as a substrate and includes a film-forming apparatus 300, a heat-processing apparatus 400 (also referred to as an annealing apparatus 400), and a plasma-processing apparatus 500. More specifically, the substrate-processing unit 2000 includes an IO stage 2100, an atmospheric transfer chamber 2200, a load lock (L/L) chamber 2300, a vacuum transfer chamber 2400, a film-forming apparatus 300, an annealing apparatus 400, and a plasma-processing apparatus 500. In the drawings, the X1 direction is the right, the X2 direction is the left, the Y1 direction is the front, and the Y2 direction is the rear.

The IO stage (load port) 2100 is installed on the front side of the substrate-processing unit 100. A plurality of storage containers (hereinafter simply referred to as “pods”) 2001 called FOUPs (Front Open Unified Pods) are mounted on the IO stage 2100. The pod 2001 is used as a carrier for transferring wafers 200, and is configured such that a plurality of unprocessed wafers 200 or processed wafers 200 are stored therein in a horizontal position.

The IO stage 2100 is adjacent to the atmospheric transfer chamber 2200. An atmospheric transfer robot 2220 that transfers the wafer 200 is installed in the atmospheric transfer chamber 2200. A load lock chamber 2300 is connected to the atmospheric transfer chamber 2200 on a side different from the IO stage 2100.

The vacuum transfer chamber (transfer module: TM) 2400 is connected to the load lock chamber 2300 on a side different from the atmospheric transfer chamber 2200.

The TM 2400 functions as a transfer chamber, which is a transfer space in which the wafer 200 is transferred under a negative pressure. The film-forming apparatus 300, the annealing apparatus 400, and the plasma-processing apparatus 500, which process the wafer 200, are connected to a housing 2410 that constitutes the TM 2400. A vacuum transfer robot 2700 that transfers the wafer 200 under a negative pressure is installed approximately at the center of the TM 2400.

The vacuum transfer robot 2700 installed inside the TM 2400 includes two arms 2800 and 2900 that can operate independently.

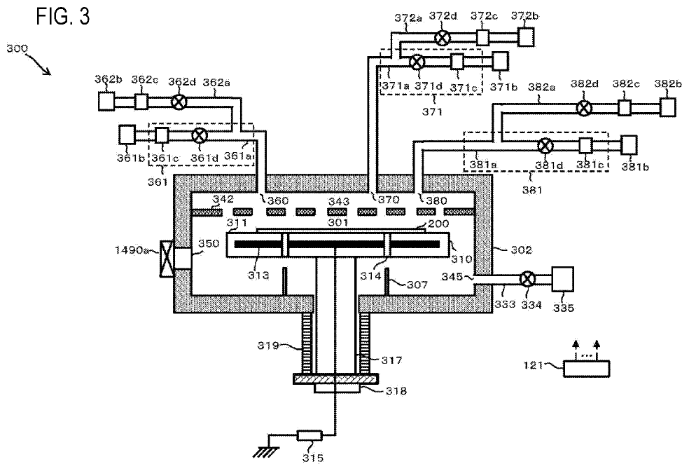

Gate valves (GV) 1490a, GV 1490b, and GV 1490c are installed between the TM 2400 and the film-forming apparatus 300, between the TM 2400 and the annealing apparatus 400, and between the TM 2400 and the plasma-processing apparatus 500, respectively. By opening the respective GVs 1490a, 1490b, and 1490c, the vacuum transfer robot 2700 in the TM 2400 can load and unload the wafer 200 through substrate-loading/unloading ports 350, 450, and 550 provided in the film-forming apparatus 300, the annealing apparatus 400, and the plasma-processing apparatus 500, respectively (see FIGS. 3, 4, and 5).

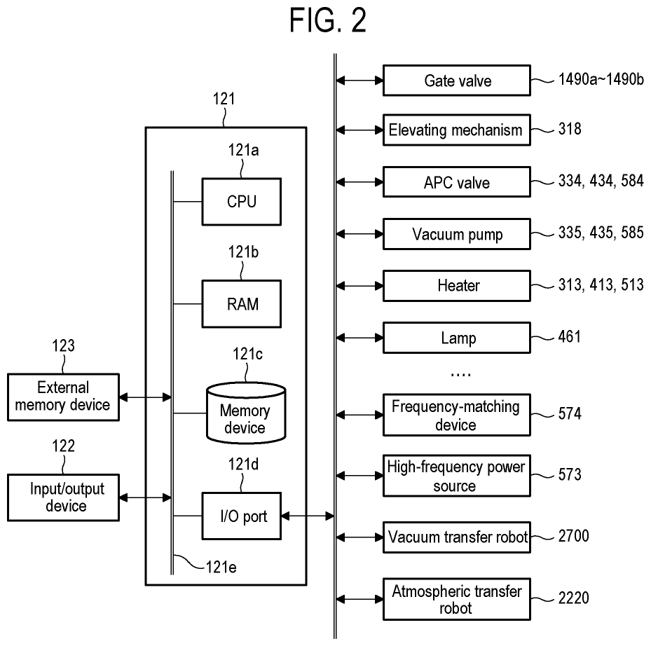

As shown in FIG. 2, the controller 121 as a control part (control means) is configured as a computer including a CPU (Central Processing Unit) 121a, a RAM (Random Access Memory) 121b, a memory device 121c, and an I/O port 121d. The RAM 121b, the memory device 121c, and the I/O port 121d are configured to be able to exchange data with the CPU 121a via an internal bus 121e. An input/output device 122 configured as, for example, a touch panel or the like is connected to the controller 121. In addition, an external memory device 123 may be connected to the controller 121.

The controller 121 controls processing operations of the substrate-processing unit 2000 that includes the film-forming apparatus 300, the annealing apparatus 400, and the plasma-processing apparatus 500.

The memory device 121c is formed of, for example, a flash memory, an HDD (Hard Disk Drive), an SSD (Solid State Drive), and the like. The memory device 121c readably stores a control program for controlling the operation of the substrate-processing apparatus, a process recipe in which procedures and conditions for a substrate-processing process are written, and the like. The process recipe is a combination of instructions that causes the controller 121 configured as a computer to have the substrate-processing apparatus execute each procedure in a substrate-processing process described below to obtain a predetermined result. The process recipe functions as a program. Hereinafter, the process recipe, the control program, and the like will be collectively and simply referred to as a program. Further, the process recipe is also simply referred to as a recipe. When the word program is used in this specification, it may include only a recipe, only a control program, or both. The RAM 121b is configured as a memory area (work area) in which programs, data, and the like read by the CPU 121a are temporarily held.

The I/O port 121d is connected to the gate valves 1490a to 1490c, the vacuum transfer robot 2700, and the atmospheric transfer robot 2220, and is also connected to an elevating mechanism 318, APC valves 334, 434, and 584, vacuum pumps 335, 435, and 585, heaters 313, 413, and 513, a lamp 416, a frequency-matching device 574, and a high-frequency power source 573, which will be described later.

The CPU 121a is configured to be able to read a control program from the memory device 121c and execute the control program, and to read a recipe from the memory device 121c in response to the input of an operation command from the input/output device 122. The CPU 121a is configured to, according to the content of the recipe thus read, control the opening/closing operations of the gate valves 1490a to 1490c, the raising/lowering operations of the elevating mechanism 318, the operation of the vacuum transfer robot 2700, the operation of the atmosphere transfer robot 2220, the opening/closing operations of the APC valves 334, 434, and 584 and the vacuum pumps 335, 435, and 585, the start/stop of the vacuum pumps 335, 435, and 585, the temperature adjustment operations of the heaters 313, 413, and 513, the temperature adjustment operation of the lamp 416, the power-matching operation of the frequency-matching device 574, the on/off operation of the high-frequency power source 573, and the like.

The controller 121 can be configured by installing the above-mentioned program stored in the external memory device 123 into a computer. The external memory device 123 includes, for example, a magnetic disk such as an HDD or the like, an optical disk such as a CD or the like, a magneto-optical disk such as an MO or the like, a semiconductor memory such as a USB memory or an SSD, and the like. The memory device 121c and the external memory device 123 are configured as computer-readable recording media. Hereinafter, these will be collectively and simply referred to a recording medium. When the term “recording medium” is used in this specification, it may include only the memory device 121c, only the external memory device 123, or both. The program may be provided to the computer using communication means such as the Internet or a dedicated line without using the external memory device 123.

### (2) Configuration of Film-Forming Apparatus

Next, the film-forming apparatus 300 used in the substrate-processing unit 2000 will be described. The film-forming apparatus 300 is used when performing a film-forming process, which is a process of manufacturing a semiconductor device, and is configured as, for example, a single-substrate type substrate-processing apparatus.

### (Process Container)

As shown in FIG. 3, the film-forming apparatus 300 includes a process container 302. A process chamber 301 for processing the wafer 200 is formed within the process container 302.

A substrate-loading/unloading port 350 adjacent to the GV 1490a is provided on the side surface of the process container 302, and the wafer 200 is moved to and from the TM 2400b through the substrate-loading/unloading port 350. Lift pins 307 are installed at the bottom of the process container 202.

A susceptor 310 serving as a substrate mounting part on which the wafer 200 is mounted is arranged within the process chamber 301. A substrate-mounting surface 311 on which the wafer 200 is mounted is provided on the upper surface of the susceptor 310. A heater 313 serving as a heating mechanism for adjusting the temperature of the wafer 200 on the substrate-mounting surface 311 is embedded in the susceptor 310. A temperature adjustment part 315 that adjusts the electric power supplied to the heater 313 is connected to the heater 313. The temperature adjustment part 315 is controlled according to instructions from the controller 121. Further, the susceptor 310 includes through-holes 314 through which the lift pins 307 passes. The through-holes 314 are formed at the positions corresponding to the lift pins 307.

The susceptor 310 is supported by a shaft 317. The shaft 317 passes through the bottom of the process container 302 and is connected to an elevating mechanism 318 outside the process container 302. The lower end of the shaft 317 is covered with a bellows 319, and the inside of the process chamber 301 is kept airtight.

### (Gas Introduction Hole)

At the upper portion of the process chamber 301, gas introduction holes 360, 370, and 380 are provided for supplying various gases into the process chamber 301. The configuration of a gas supply system connected to the gas introduction holes 360, 370, and 380 will be described later.

### (Gas Supply System)

A precursor (gas) supply pipe 361a, a catalyst supply pipe 371a, and a reaction gas supply pipe 381a are connected to the gas introduction holes 360, 370, and 380, respectively. A precursor (the details of which will be described later) is mainly supplied from a precursor (gas) supply system 361 including a precursor supply pipe 361a. A catalyst (the details of which will be described later) is mainly supplied from a catalyst supply system 371 including a catalyst supply pipe 371a. A reaction gas is mainly supplied from a reaction gas supply system 381 including a reaction gas supply pipe 381a.

### (Precursor Supply System)

In the precursor supply pipe 361a, a precursor (gas) supply source 361b, a mass flow controller (MFC) 361c as a flow rate controller (flow rate control part), and a valve 361d as an opening/closing valve are installed sequentially from the upstream side.

The downstream end of the first inert gas supply pipe 362a is connected to the precursor supply pipe 361a on the downstream side of the valve 361d. In the first inert gas supply pipe 362a, an inert gas supply source 362b, an MFC 362c, and a valve 362d are installed sequentially from the upstream side.

### (Catalyst Supply System)

In the catalyst supply pipe 371a, a catalyst supply source 371b, an MFC 371c, and a valve 371d are installed sequentially from the upstream side.

A downstream end of a second inert gas supply pipe 372a is connected to the catalyst supply pipe 371a on the downstream side of the valve 371d. In the second inert gas supply pipe 372a, a second inert gas supply source 372b, an MFC 372c, and a valve 372d are installed sequentially from the upstream side.

### (Reaction Gas Supply System)

In the reaction gas supply pipe 381a, a reaction gas supply source 381b, an MFC 381c, and a valve 381d are installed sequentially from the upstream side.

A downstream end of a third inert gas supply pipe 382a is connected to the reaction gas supply pipe 381a on the downstream side of the valve 381d. In the third inert gas supply pipe 382a, a third inert gas supply source 382b, an MFC 382c, and a valve 382d are installed sequentially from the upstream side.

In addition, in this specification, the precursor (gas), the reaction gas, and the catalyst gas are also individually or collectively referred to as a film-forming gas. Further, the precursor supply system 361, the catalyst supply system 371, and the reaction gas supply system 381 are also individually or collectively referred to as a film-forming gas supply system.

### (Exhaust System)

An exhaust port 345 for exhausting the atmosphere inside the process chamber 301 is provided on the inner wall side of the process container 302. An exhaust pipe 333 is connected to the side surface of the outer wall of the process container 302 so as to communicate with the exhaust port 345. In the exhaust pipe 333, an APC (Auto Pressure Controller) valve 334 as a pressure regulator (pressure regulation part), and a vacuum pump 335 as an evacuation device are installed sequentially from the upstream side. Mainly, the exhaust port 355, exhaust pipe 333, and the APC valve 334 are collectively referred to as an exhaust system.

### (3) Configuration of Annealing Apparatus

Next, the annealing apparatus 400 used in the above-described substrate-processing unit 2000 will be described. The annealing apparatus 400 is used when performing heat processing (also referred to as annealing processing), which is a process of manufacturing a semiconductor device, and is configured as, for example, a single-substrate type substrate-processing apparatus.

### (Process Container)

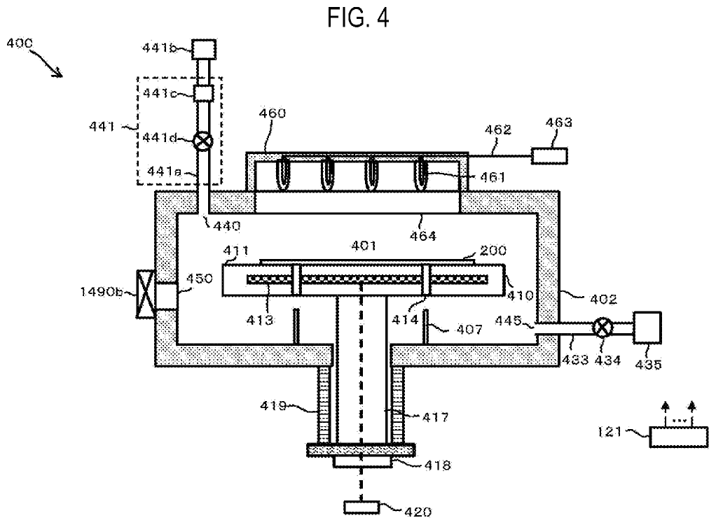

As shown in FIG. 4, the annealing apparatus 400 includes a process container 402. A process chamber 401 for processing the wafer 200 is formed within the process container 402.

A substrate-loading/unloading port 450 adjacent to the GV 1490b is provided on the side surface of the process container 402, and the wafer 200 is moved to and from the TM 2400 through the substrate-loading/unloading port 450. Lift pins 407 are provided at the bottom of the process container 402.

A susceptor 410 serving as a substrate mounting part on which the wafer 200 is mounted is arranged within the process chamber 401. A substrate-mounting surface 411 on which the wafer 200 is mounted is provided on the upper surface of the susceptor 410. A heater 413 serving as a heating mechanism for adjusting the temperature of the wafer 200 on the substrate-mounting surface 411 is embedded in the susceptor 410. A heater controller 420 that adjusts the temperature of the heater 413 is connected to the heater 413. The on/off operation of the heater 413 and the like are controlled by the heater controller 420 according to instructions from the controller 121. Further, the susceptor 410 includes through-holes 414 through which the lift pins 407 passes. The through-holes 414 are formed at the positions corresponding to the lift pins 407.

The susceptor 410 is supported by a shaft 417. The shaft 417 passes through the bottom of the process container 402 and is connected to an elevating mechanism 418 outside the process container 402. The lower end of the shaft 417 is covered with a bellows 419, and the inside of the process chamber 401 is kept airtight.

### (Lamp)

A lamp house 460 is installed on the ceiling of the process container 402 at a position facing the surface of the wafer 200. The lamp house 460 is provided with a plurality of lamps 461 as heating mechanisms.

The lamps 461 are connected to a lamp controller 463 via a wiring 462. The on/off operations of the lamps 461 and the like are controlled by the lamp controller 463 according to instructions from the controller 121.

A window 464 is provided on the ceiling of the process container 402 at a position facing the lamps 461. The window 464 is vacuum-resistant and made of a material that does not block the heat radiated from the lamps 461, such as quartz or the like.

### (Gas Introduction Hole)

A gas introduction hole 440 for supplying an inert gas into the process chamber 401 is provided in the upper portion of the process chamber 401.

### (Inert Gas Supply System)

An inert gas supply pipe 441a is connected to the gas introduction hole 440. An inert gas (the details of which will be described later) is supplied from an inert gas supply system 441 including an inert gas supply pipe 441a. In the inert gas supply pipe 441a, an inert gas supply source 441b, an MFC 441c, and a valve 441d are installed sequentially from the upstream side.

### (Exhaust System)

An exhaust port 445 for exhausting the atmosphere inside the process chamber 401 is provided on the inner wall side of the process container 402. An exhaust pipe 433 is connected to the side surface of the outer wall of the process container 402 to communicate with the exhaust port 445. In the exhaust pipe 433, an APC valve 434 as a pressure regulator (pressure regulation part), and a vacuum pump 435 as an evacuation device are installed sequentially from the upstream side. Mainly, the exhaust port 455, the exhaust pipe 433, and the APC valve 434 are collectively referred to as an exhaust system.

### (4) Configuration of Plasma-Processing Apparatus

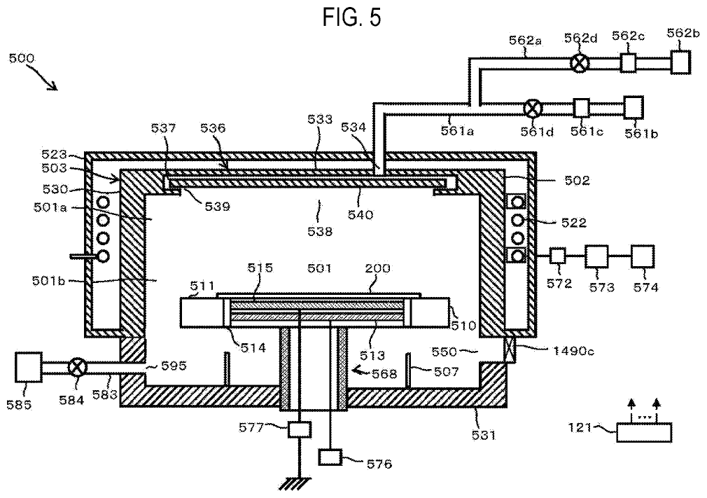

Next, the plasma-processing apparatus 500 used in the above-described substrate-processing unit 2000 will be described. The plasma-processing apparatus 500 is used when performing a film-forming process, which is a process of manufacturing a semiconductor device, and is configured as, for example, a single-substrate type substrate-processing apparatus. FIG. 5 is a schematic configuration diagram of the plasma-processing apparatus 500 according to the present embodiment.

### (Process Chamber)

As shown in FIG. 5, the plasma-processing apparatus 500 includes a process furnace 502 that accommodates the wafer 200 and performs plasma processing to the wafer 200. The process furnace 502 includes a process container 503 that constitutes a process chamber 501. The process container 503 includes an upper container 530 and a lower container 531. The process chamber 501 is formed by placing the upper container 530 over the lower container 531.

A substrate-loading/unloading port 550 adjacent to the GV 1490c is provided in the lower side wall of the lower container 531, and the wafer 200 is moved to and from the TM 2400 through the substrate-loading/unloading port 580. Lift pins 507 are provided at the bottom of the process container 503.

The process chamber 501 includes a plasma generation space 501a around which a resonance coil 522 is installed, and a substrate processing space 501b that communicates with the plasma generation space 501a and processes the wafer 200 therein. The plasma generation space 501a is a space where plasma is generated, and is a space above the lower end of the resonance coil 522 and below the upper end of the resonance coil 522 in the process chamber 501. The substrate processing space 501b is a space in which the wafer 200 is processed using plasma, and is a space below the lower end of the resonance coil 522.

A susceptor 510 serving as a substrate mounting part on which the wafer 200 is mounted is arranged within the process chamber 501. A substrate-mounting surface 511 on which the wafer 200 is mounted is provided on the upper surface of the susceptor 510.

A heater 513 serving as a heating mechanism for adjusting the temperature of the wafer 200 on the substrate-mounting surface 511 is embedded in the susceptor 510. By supplying electric power to the heater 513 via a heater power adjustment mechanism 576, the surface of the wafer 200 can be heated to a predetermined degree within the range of, for example, 25 degrees C. to 1000 degrees C.

The susceptor 510 is electrically insulated from the lower container 531. An impedance adjustment electrode 515 is provided inside the susceptor 510. The impedance adjustment electrode 515 is grounded via an impedance changing mechanism 577 serving as an impedance adjustment part. The potential (bias voltage) of the wafer 200 during plasma processing can be controlled via the impedance adjustment electrode 515 and the susceptor 510.

A susceptor elevating mechanism 568 for raising and lowering the susceptor 510 is installed below the susceptor 510. A through-hole 514 is provided in the susceptor 510. Lift pins 507 serving as support bodies for supporting the wafer 200 are installed on the bottom surface of the lower container 531. When the susceptor 510 is lowered by the susceptor elevating mechanism 568, the lift pins 507 penetrate the through-holes 514 without contacting the susceptor 510. This makes it possible to hold the wafer 200 from below.

A gas supply head 536 is installed above the process chamber 501, i.e., above the upper container 530. The gas supply head 536 includes a lid 533, a gas introduction hole 534, a buffer chamber 537, an opening 538, a shielding plate 540, and a gas discharge hole 539, and is configured to supply a gas into the process chamber 501.

### (Gas Supply System)

A hydrogen (H)-containing gas supply pipe 561a is connected to the gas introduction hole 534. A hydrogen-containing gas (the details of which will be described later) is mainly supplied from a H-containing gas supply system, which will be described later.

In the H-containing gas supply pipe 561a, an H-containing gas supply source 561b, an MFC 561c, and a valve 561d as an opening/closing valve are installed sequentially from the upstream side.

A downstream end of a fourth inert gas supply pipe 562a is connected to the H-containing gas supply pipe 561a on the downstream side of the valve 561d. In the fourth inert gas supply pipe 562a, an inert gas supply source 562b, an MFC 562c, and a valve 562d are installed sequentially from the upstream side.

### (Exhaust System)

An exhaust port 595 for exhausting the atmosphere inside the process chamber 501 is provided on the inner wall side of the lower container 531. An exhaust pipe 583 is connected to the outer wall side of the lower container 531 to communicate with the exhaust port 595. In the exhaust pipe 583, an APC valve 584 as a pressure regulator (pressure regulation part), and a vacuum pump 585 as an evacuation device are installed sequentially from the upstream side. Mainly, the exhaust port 595, the exhaust pipe 583, and the APC valve 584 are collectively referred to as an exhaust system.

A spiral resonance coil 522 is installed on the outer periphery of the process chamber 501, i.e., on the outside of the side wall of the upper container 530, to surround the process chamber 501. An RF (Radio Frequency) sensor 572, a high-frequency power source 573, and a frequency-matching device 574 (frequency controller) are connected to the resonance coil 522. A plasma generator (plasma excitation part) mainly includes the resonance coil 522, the RF sensor 572, the high-frequency power source 573, and the frequency-matching device 574. A shielding plate 223 is installed on the outer peripheral side of the resonance coil 212.

### (5) Substrate-Processing Process

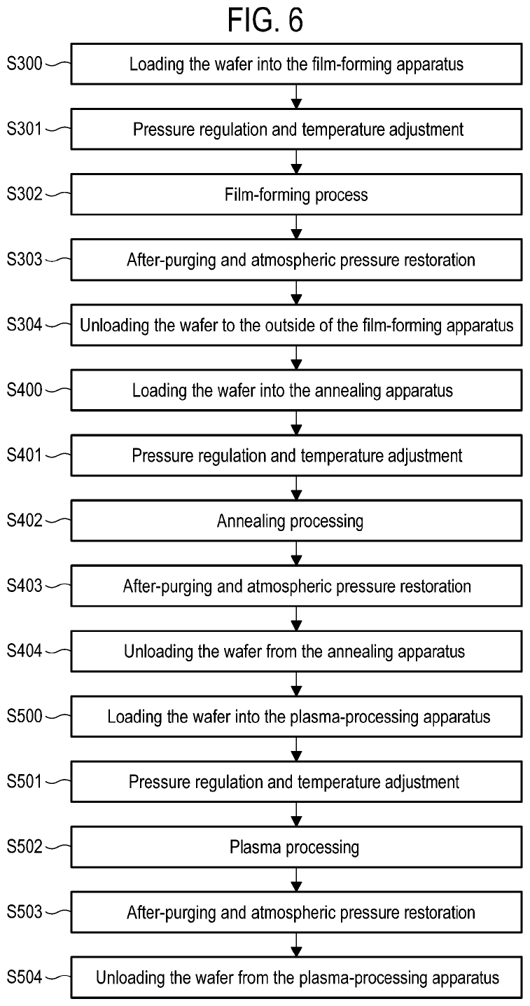

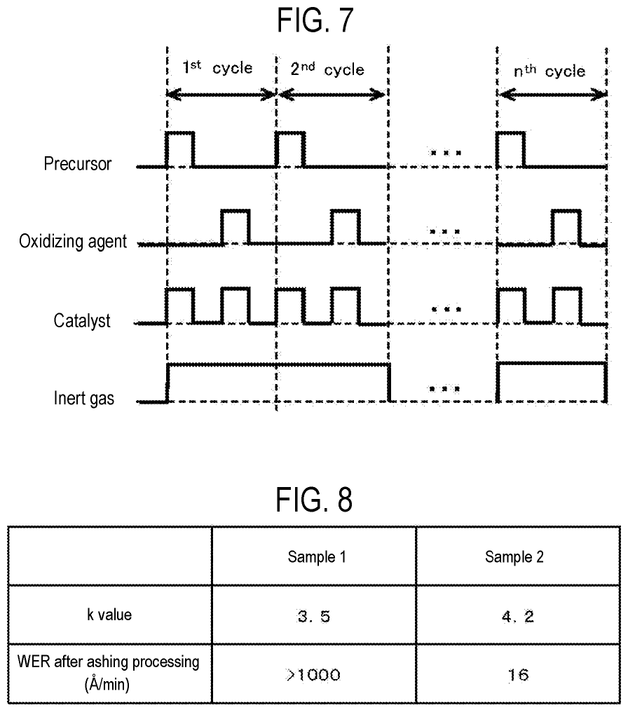

An example of a substrate-processing sequence in which, by using the above-described substrate-processing unit 2000, as a process of manufacturing a semiconductor device, a first film is formed on a wafer 200 as a substrate in the film-forming apparatus 300, the first film is subjected to heat processing (annealing processing) in the annealing apparatus 400 to modify the first film into a second film, and the second film is subjected to plasma processing in the plasma-processing apparatus 500 to modify the second film into a third film will be described mainly with reference to FIGS. 6 and 7. In the following description, the operation of each part constituting the substrate-processing unit 2000 is controlled by the controller 121.

The substrate-processing sequence according to the present embodiment includes:
step a of providing a wafer 200 on which a first film containing at least one selected from the group of a combination of C—H bonds and Si—C bonds and a combination of N—H bonds and Si—N bonds is formed;
step b of modifying the first film into a second film by performing heat processing to the first film at a processing temperature higher than a processing temperature at which the first film is formed;
step c of modifying the second film into a third film by performing plasma processing to the second film so that the ratio of Si—C bonds to C—H bonds in the third film is made larger than the ratio of Si—C bonds to C—H bonds in the first film, or the ratio of Si—N bonds to N—H bonds in the third film is made larger than the ratio of Si—N bonds to N—H bonds in the first film.

In the present embodiment, there will be described an example in which in step a, a silicon oxycarbonate film (SiOC film) is formed on the wafer 200 as the first film containing C—H bonds and Si—C bonds by alternately performing supplying a precursor containing at least C—H bonds and Si—C bonds and a catalyst to the wafer 200 and supplying an oxidizing agent as a reaction gas and a catalyst to the wafer 200. Further, in the present embodiment, there will be described an example in which in step c, a hydrogen gas (H₂ gas) as a H-containing gas is excited into a plasma state and supplied to the second film.

The SiOC film is a low-k film with a low dielectric constant, and is an insulating film with high resistance to hydrogen fluoride (HF) etching (hereinafter referred to as HF resistance). Therefore, the SiOC film is widely used, for example, as a spacer film. Meanwhile, the SiOC film is sometimes subjected to oxidation processing such as oxygen (O₂) plasma ashing after film formation as a process of manufacturing a semiconductor device. When the SiOC film is subjected to ashing processing (oxidation processing), the HF resistance thereof may deteriorate, and as a result, the function thereof as a spacer film may be impaired. In the present embodiment, there will be described a SiOC film that maintains both low dielectric constant and high HF resistance even when ashing processing is performed after film formation. Hereinafter, the HF resistance of a film after ashing processing is sometimes referred to as ashing resistance.

In this specification, the above-described substrate-processing sequence may be denoted as follows for the sake of convenience. The same notation will be used in the following description of modifications and other embodiments.

$$( precursor + catalyst \to oxidizing agent + catalyst ) \times n \to heat processing ( annealing processing ) \to plasma - excited {H}_{2} gas \to S i O C film$$

(Wafer Loading into Film-Forming Apparatus 300: S300)

The wafer 200 to be processed is taken out from the pod 2001 on the IO stage 2100 by the atmospheric transfer robot 2220. With the susceptor 310 lowered to a predetermined transfer position, the GV 1490a is opened and the wafer 200 is loaded from the TM 2400 into the process chamber 301 by the vacuum transfer robot 2700. The wafer 200 loaded into the process chamber 301 is supported in a horizontal posture on the lift pins 307 that protrude upward from the substrate-mounting surface 311 of the susceptor 310. After loading the wafer 200 into the process container 302, the vacuum transfer robot 2700 is moved out of the process chamber 301 and the GV 1490a is closed. Thereafter, the susceptor 310 is raised to a predetermined processing position, and the wafer 200 to be processed is delivered from the lift pins 307 onto the susceptor 310.

### (Pressure Regulation and Temperature Adjustment: S301)

Subsequently, the inside of the process chamber 301 is evacuated by the vacuum pump 335 so that a desired processing pressure is achieved. The pressure inside the process chamber 301 is measured by a pressure sensor, and the APC valve 334 is feedback-controlled based on the measured pressure information. Further, the wafer 200 is heated by the heater 313 so that the wafer 200 has a desired processing temperature. When the inside of the process chamber 301 reaches the desired processing pressure and the temperature of the wafer 200 reaches the desired processing temperature and stabilizes at that temperature, a film-forming process to be described later is started.

### (Film-Forming Process: S302)

In this step (step a), the following steps a1 and a2 are executed.

[Step a1]

In step a1, a precursor (precursor gas) and a catalyst (catalyst gas) are supplied as film-forming agents to the wafer 200 in the process chamber 301.

Specifically, the valves 361d and 371d are opened to allow the precursor and the catalyst to flow into the precursor supply pipe 361a and the catalyst supply pipe 371a, respectively. The flow rates of the precursor and the catalyst are adjusted by the MFCs 361c and 371c, respectively. The precursor and the catalyst are supplied into the process chamber 301 via the buffer chamber 343, mixed within the process chamber 301, and exhausted from the exhaust port 345. At this time, the precursor and the catalyst are supplied to the wafer 200 from above the wafer 200 (precursor+catalyst supply). At this time, the valves 362d, 372d, and 382d are opened to supply an inert gas into the process chamber 301 through the precursor supply pipe 361a, the catalyst supply pipe 371a, and the reaction gas supply pipe 381a, respectively. In some of the methods described below, the supply of the inert gas may not be performed.

Processing conditions when supplying the precursor and the catalyst in this step (step a1) are exemplified as follows.
Processing temperature: room temperature (25 degrees C.) to 120 degrees C., preferably room temperature to 90 degrees C.
Processing pressure: 133 to 1333 Pa
Precursor supply flow rate: 0.001 to 2 slm
Catalyst supply flow rate: 0.001 to 2 slm
Inert gas supply flow rate (for each gas supply pipe): 0 to 20 slm
Each gas supply time: 1 to 60 seconds

In this specification, the notation of a numerical range such as “25 to 120 degrees C.” means that the lower limit and upper limit are included in the range. Therefore, for example, “450 to 750 degrees C.” means “450 degrees C. or more and 750 degrees C. or less.” The same applies to other numerical ranges. Further, in this specification, the processing temperature means the temperature of the wafer 200 or the temperature inside the process chamber 301, and the processing pressure means the pressure inside the process chamber 301. Furthermore, when the supply flow rate includes 0 slm, the 0 slm means a case where a gas is not supplied. The same applies to the following description.

By supplying a chlorosilane-based gas containing C—H bonds and Si—C bonds as a precursor to the wafer 200 under the above-mentioned conditions, a silicon (Si) containing layer containing C, H, and Cl is formed as a first layer on the outermost surface of the wafer 200. The Si-containing layer containing C, H, and Cl is a layer containing C—H bonds and Si—C bonds. In this specification, for the sake of convenience, the Si-containing layer containing C, H, and Cl is also simply referred to as a Si-containing layer containing C or a SiC layer.

By supplying the precursor to the wafer 200 under the above conditions, at least a portion of both Si—C bonds and C—H bonds contained in the precursor can be directly taken into (allowed to remain in) the first layer while retaining it without being broken.

The first layer includes a continuous layer made of Si and containing C, H, and Cl, a discontinuous layer, and a Si thin film containing C, H, and Cl formed by overlapping these layers. The Si constituting the Si layer containing C, H, and Cl includes Si whose bonds with C and Cl are not completely broken, as well as Si whose bonds with C and Cl are completely broken.

In this step, by supplying the catalyst together with the precursor, the above-mentioned reaction can be caused to proceed in a non-plasma atmosphere and under the above-mentioned low temperature conditions.

Furthermore, by forming the first layer in a non-plasma atmosphere and under the above-mentioned low temperature conditions, the precursor can be prevented from thermal decomposition (vapor phase decomposition), i.e., autolysis, in the process chamber 301. This makes it possible to adsorb the precursor onto the wafer 200 and form a precursor adsorption layer.

After the first layer is formed, the valves 361d and 371d are closed to stop the supply of the precursor and the catalyst into the process chamber 301. Then, the inside of the process chamber 301 is evacuated to remove the gas and the like remaining in the process chamber 301 from the inside of the process chamber 301. At this time, the valves 362d, 372d, and 382d are kept open to maintain the supply of the inert gas into the process chamber 301. The inert gas acts as a purge gas, thereby purging the inside of the process chamber 301.

As the precursor, for example, a silane-based gas containing Si as a main element constituting the film formed on the wafer 200 may be used. As the silane-based gas, for example, a gas containing Si and a halogen, i.e., a halosilane-based gas may be used. The halogen includes chlorine (Cl), fluorine (F), bromine (Br), iodine (I), and the like. As the halosilane-based gas, for example, the above-mentioned chlorosilane-based gas containing Si and Cl may be used.

As the precursor, for example, an alkylenechlorosilane-based gas such as a bis(trichlorosilyl)methane ((SiCl₃)₂CH₂, abbreviation: BTCSM) gas, a 1,2-bis(trichlorosilyl)ethane ((SiCl₃)₂C₂H₄, abbreviation: BTCSE) gas, and the like may be used.

As the precursor, for example, an alkylchlorosilane-based gas such as a 1,1,2,2-tetrachloro-1,2-dimethyldisilane ((CH₃)₂Si₂Cl₄, abbreviation: TCDMDS) gas, a 1,2-dichloro-1,1,2,2-tetramethyldisilane ((CH₃)₄Si₂Cl₂, abbreviation: DCTMDS) gas, and the like may be used.

As the precursor, a gas containing a cyclic structure containing Si and C and a halogen, such as a 1,1,3,3-tetrachloro-1,3-disilacyclobutane (C₂H₄Cl₄Si₂, abbreviation: TCDSCB) gas, and the like, may be used.

As described above, it is preferable to use gases containing C—H bonds and Si—C bonds as the precursor. One or more of these gases may be used as the precursor.

As the catalyst, for example, an amine-based gas containing carbon (C), nitrogen (N), and H may be used. As the amine-based gas, for example, a cyclic amine gas such as a pyridine (Py) gas, an aminopyridine (C₅H₆N₂) gas, a picoline (C₆H₇N) gas, a lutidine (C₇H₉N) gas, a piperazine (C₄H₁₀N₂) gas, a piperidine (C₅H₁₁N) gas, or the like, a chain amine gas such as a triethylamine ((C₂H₅)₃N, abbreviation: TEA) gas, a diethylamine ((C₂H₅)₂NH, abbreviation: DEA) gas, or the like, and the like may be used. In addition to these gases, for example, an ammonia (NH₃) gas, and the like may also be used as the catalyst. As the catalyst, one or more of these gases may be used. This point also applies to step a2, which will be described later.

As described above, it is preferable to use gases containing Si and H and at least one selected from the group of C and N as the film-forming gases (the precursor and the catalyst).

As the inert gas, for example, a nitrogen (N₂) gas, and a rare gas such as an argon (Ar) gas, a helium (He) gas, a neon (Ne) gas, a xenon (Xe) gas or the like may be used. One or more of these gases may be used as the inert gas. This point also applies to each step described below.

[Step a2]

After step a1 is completed, an oxidizing agent (oxidizing gas) and a catalyst (catalyst gas) are supplied to the wafer 200, i.e., the Si-containing layer formed on the wafer 200, in the process chamber 201.

Specifically, the valves 381d and 371d are opened to allow the oxidizing agent and the catalyst to flow into the reaction gas supply pipe 381a and the catalyst supply pipe 371a, respectively. The flow rates of the oxidizing agent and the catalyst are adjusted by the MFCs 381c and 371c, respectively. The oxidizing agent and the catalyst are supplied into the process chamber 301 via the buffer chamber 343, mixed within the process chamber 301, and exhausted from the exhaust port 345. At this time, the oxidizing agent and the catalyst are supplied to the wafer 200 from above the wafer 200 (oxidizing agent+catalyst supply). At this time, the valves 362d, 372d, and 382d are kept open to maintain the supply of the inert gas into the process chamber 301.

Processing conditions when supplying the oxidizing agent and the catalyst in this step (step a2) are exemplified as follows.

Processing temperature: room temperature (25 degrees C.) to 120 degrees C., preferably room temperature to 100 degrees C.
Oxidizing agent supply flow rate: 0.001 to 2 slm
Catalyst supply flow rate: 0.001 to 2 slm

Other processing conditions are the same as those in step a1.

By supplying the oxidizing agent to the wafer 200 under the above conditions, at least a portion of the first layer formed on the wafer 200 in step a1 is oxidized (modified). As a result, a silicon oxycarbonate layer (SiOC layer) is formed on the outermost surface of the wafer 200 as a second layer formed by oxidizing the first layer. When forming the second layer, impurities such as Cl contained in the first layer constitute a gaseous substance containing at least Cl during the modifying reaction process, and are discharged from the process chamber 301. Thus, the second layer becomes a layer containing less impurities such as Cl than the first layer formed in step a1.

By supplying the oxidizing agent to the wafer 200 under the above-mentioned processing conditions, at least a part of both the Si—C bonds and the C—H bonds contained in the first layer can be directly taken into (allowed to remain in) the second layer while retaining it without being broken. By supplying the oxidizing agent to the wafer 200 under the above-mentioned processing conditions, the second layer thus formed becomes a layer containing moisture, i.e., an OH group.

In this step, as in step a1, by supplying the catalyst together with the oxidizing agent, the above-mentioned reaction can be caused to proceed in a non-plasma atmosphere and under low temperature conditions as described below.

After the second layer is formed, the valves 381d and 371d are closed to stop the supply of the oxidizing agent into the process chamber 301. Then, the inside of the process chamber 301 is evacuated to remove the gas and the like remaining in the process chamber 301 from the inside of the process chamber 301. At this time, the gas remaining in the process chamber 301 is removed from the process chamber 301 using the same processing procedure as in the purging in step a1 (purging).

As the oxidizing agent, for example, an oxygen (O)-containing gas or an oxygen (O)- and hydrogen (H)-containing gas may be used. As the O-containing gas, for example, an oxygen (O₂) gas, an ozone (O₃) gas, a nitrous oxide (N₂O) gas, a nitrogen monoxide (NO) gas, a nitrogen dioxide (NO₂) gas, a carbon monoxide (CO) gas, a carbon dioxide (CO₂) gas, and the like may be used. As the O- and H-containing gas, for example, water vapor (H₂O gas), hydrogen peroxide (H₂O₂), hydrogen (H₂) gas+oxygen (O₂) gas, H₂ gas+ozone (O₃) gas, and the like may also be used. The O- and H-containing gas is also an O-containing gas. As the oxidizing agent, in addition to these gases, a cleaning liquid, for example, a cleaning liquid containing aqueous ammonia, hydrogen peroxide, and pure water may be used. That is, oxidation may be performed by APM cleaning. In this case, oxidation can be performed by exposing the wafer 200 to a cleaning liquid. As described above, the oxidizing agent may be a gaseous substance or a liquid substance. Further, the oxidizing agent may be a liquid substance such as a mist-like substance. As the oxidizing agent, one or more of these substances may be used.

### [Performing a Cycle a Predetermined Number of Times]

By performing a cycle that performs the above-described steps a1 and a2 non-simultaneously, i.e., without synchronization, a predetermined number of times (n times where n is an integer of 1 or more), a SiOC film containing Si, O, and C and having a predetermined thickness can be formed as the first film on the wafer 200. Preferably, the above-described cycle is repeated multiple times. That is, it is preferable that the thickness of the second layer (SiOC layer) formed per cycle is set to be smaller than a desired film thickness, and the above cycle is repeated multiple times until the thickness of the SiOC film as the first film formed by stacking the second layers reaches the desired thickness.

By performing step a under the above-mentioned conditions, at least a part of at least one selected from the group of the C—H bonds and the Si—C bonds contained in precursor can be directly taken into (allowed to remain in) the first film (SiOC film) while retaining it without being broken.

Furthermore, by performing step a under the above-mentioned conditions, the first film (SiOC film) formed on the wafer 200 becomes a film containing moisture, i.e., an OH group, on its surface.

### (After-Purging and Atmospheric Pressure Restoration: S303)

When the process of forming the first film (SiOC film) having a desired thickness on the wafer 200 is completed, the inside of the process chamber 301 is evacuated to remove the gas and the like remaining in the process chamber 301 from the inside of the process chamber 301. Then, the gaseous substances remaining in the process chamber 301 are removed from the process chamber 201 using the same processing procedure and processing conditions as those for the above-described purging (after-purging). Thereafter, the atmosphere inside the process chamber 301 is replaced with a purge gas, and the pressure inside the process chamber 301 is returned to the atmospheric pressure (atmospheric pressure restoration).

### (Unloading the Wafer to the Outside of the Film-Forming Apparatus 300: S304)

Thereafter, the susceptor 310 is lowered to a predetermined transfer position, and the wafer 200 is transferred from the susceptor 310 onto the lift pins 307. Thereafter, the GV 1490a is opened, and the processed wafer 200 is unloaded to the outside of the process container 302 (TM 2400) by the vacuum transfer robot 2700.

(Wafer Loading into the Annealing Apparatus 400: S400)

With the susceptor 410 lowered to the predetermined transfer position, the GV 1490b is opened and the wafer 200 is transferred from the TM 2400 into the process chamber 401 by the vacuum transfer robot 2700. The wafer 200 loaded into the process chamber 401 is supported in a horizontal posture on the lift pins 407 that protrude upward from the substrate-mounting surface 411 of the susceptor 410. After the loading of the wafer 200 into the process chamber 401 is completed, the vacuum transfer robot 2700 is removed from the process chamber 401, and the GV 1490b is closed. Thereafter, the susceptor 410 is raised to a predetermined processing position, and the wafer 200 to be processed is delivered from the lift pins 407 onto the susceptor 410.

### (Pressure Regulation and Temperature Adjustment: S401)

Subsequently, as in S301, the vacuum pump 435 and the APC valve 434 perform pressure control, and the heater 413 and lamp 461 perform heating control.

### (Heat Processing (Annealing Processing): S402)

The wafer 200 in the process chamber 401 is heated, and the first film (SiOC film) formed on the wafer 200 is subjected to heat processing. At this time, the valve 441d is opened to allow an inert gas to flow into the inert gas supply pipe 441a. The flow rate of the inert gas is adjusted by the MFC 441c. The inert gas is supplied into the process chamber 401, and is exhausted from the exhaust port 445. At this time, the inert gas is supplied to the wafer 200 from above the wafer 200.

Processing conditions in this step (step b) are exemplified as follows.
Processing temperature: 200 to 1000 degrees C., preferably 500 to 700 degrees C.
Processing pressure: 133 to 1333 Pa
Inert gas supply flow rate: 0.001 to 20 slm
Inert gas supply time: 1 to 120 minutes, preferably 1 to 60 minutes

By performing the heat processing to the first film formed on the wafer 200 under the above processing conditions, water contained in the first film can be removed from the first film. More specifically, by setting the processing temperature in this step to, for example, a relatively high processing temperature higher than the processing temperature in the above-described film-forming process (step a), it is possible to efficiently remove the impurities such as moisture included in the first film (OH groups present on the surface of the first film), Cl and the like. In this way, a second film is formed on the wafer 200 by removing impurities such as moisture and Cl from the first film. By removing moisture and impurities in the first film under the above-mentioned processing conditions, the second film can be made into a low-k film having a lower dielectric constant than the first film, or the second film can be maintained as a low-k film having the same dielectric constant as the first film.

By performing the heat processing to the first film formed on the wafer 200 under the above-mentioned processing conditions, at least a part of at least one selected from the group of the Si—C bonds and C—H bonds contained in the first film are removed can be taken into (allowed to remain in) the second film while retaining it without being broken. Further, under the above-mentioned processing conditions, at least a part of Si, O, and C contained in the first film is allowed to remain in the second film without being removed.

### (After-Purging and Atmospheric Pressure Restoration: S403)

After the heat processing is completed, the inside of the process chamber 401 is evacuated to remove the gas and the like remaining in the process chamber 401 from the inside of the process chamber 401. Then, the gaseous substances remaining in the process chamber 401 are removed from the inside of the process chamber 401 using the same processing procedure and processing conditions as the above-described purging (after-purging). Thereafter, the atmosphere inside the process chamber 401 is replaced with the purge gas, and the pressure inside the process chamber 401 is returned to the atmospheric pressure (atmospheric pressure restoration).

### (Unloading the Wafer to the Outside of the Annealing Apparatus 400: S404)

Thereafter, the susceptor 410 is lowered to a predetermined transfer position, and the wafer 200 is delivered from the susceptor 410 onto the lift pins 407. Thereafter, the GV 1490b is opened, and the processed wafer 200 is unloaded to the outside of the process container 402 (TM 2400) by the vacuum transfer robot 2700.

(Wafer Loading into the Plasma-Processing Apparatus 500: S500)

With the susceptor 510 lowered to a predetermined transfer position, the GV 1490c is opened, and the wafer 200 is loaded from the TM 2400 into the process chamber 501 by the vacuum transfer robot 2700. The wafer 200 loaded into the process chamber 501 is supported in a horizontal posture on the lift pins 507 that protrude upward from the substrate-mounting surface 511 of the susceptor 510. After loading the wafer 200 into the process chamber 501, the vacuum transfer robot 2700 is moved out of the process chamber 501, and the GV 1490c is closed. Thereafter, the susceptor 510 is raised to the predetermined processing position, and the wafer 200 to be processed is delivered from the lift pins 507 onto the susceptor 510.

### (Pressure Regulation and Temperature Adjustment: S501)

Subsequently, as in S301 and S401, the pressure is controlled by the vacuum pump 585 and the APC valve 584, and heating is performed by the heater 513. When the inside of the process chamber 501 reaches a desired processing pressure and the temperature of the wafer 200 reaches a desired processing temperature and stabilizes at that temperature, plasma processing, which will be described later, is started.

### (Plasma Processing: S502)

A H₂ gas is excited into a plasma state and supplied to the wafer 200 in the process chamber 501, i.e., the second film formed on the wafer 200.

Specifically, the valve 561d is opened to allow the H₂ gas to flow into the gas supply pipe 561a. The flow rate of the H₂ gas is adjusted by the MFC 561c. The H₂ gas is supplied into the process chamber 501 via the buffer chamber 537, and is exhausted from the exhaust port 595. At this time, the H₂ gas is supplied to the wafer 200 from above the wafer 200 (H₂ gas supply). At this time, the valve 562d may be opened to supply an inert gas into the process chamber 501 via the buffer chamber 537.

At this time, high-frequency (RF) power is applied to the resonance coil 522 from the high-frequency power source 573. As a result, induced plasma having a donut shape in a plan view is excited at height positions corresponding to the upper and lower grounding points and the electrical midpoint of the resonance coil 522 in the plasma generation space 501a. Excitation of the induced plasma activates the H₂ gas, thereby generating reactive species such as excited H atoms (H*) or ionized H atoms. The symbol * means radicals. The same applies to the following description. Then, plasma processing is performed mainly by the reactive species on the second film formed on the wafer 200 in step b.

Processing conditions in this step (step c) are exemplified as follows.
Processing temperature: 100 to 850 degrees C., preferably 450 to 600 degrees C.
Processing pressure: 667 to 26664 Pa, preferably 6666 to 13332 Pa
H₂ gas supply flow rate: 0.1 to 10 slm, preferably 0.15 to 0.5 slm
H₂ gas supply time: 5 to 600 seconds, preferably 30 to 300 seconds
RF power: 100 to 5000 W, preferably 500 to 3500 W
RF frequency: 800 kHz to 50 MHz

By performing plasma processing to the second film formed on the wafer 200 under the above-described processing conditions, the second film can be modified into a third film. Specifically, while the Si—C bonds contained in the second film are retained in the third film, at least a part of the C—H bonds contained in the second film can be broken. More specifically, for example, by setting the processing temperature in this step to a higher processing temperature than the processing temperature in the above-described film-forming process (step a), at least a part of the C—H bonds contained in the second film can be broken while the Si—C bonds contained in the second film are retained intact in the third film. Meanwhile, even if the processing temperature in this step is, for example, a relatively low processing temperature lower than the processing temperature in the above-described heat processing (step b), at least a part of the C—H bonds contained in the second film can be broken while the Si—C bonds contained in the second film are retained intact in the third film.

Then, as the bonding hand of C in the C—H bond in which H is broken is bonded to Si present in the third film, the ratio of Si—C bonds to C—H bonds in the third film can be made larger than the ratio of Si—C bonds to C—H bonds in the first film. In addition, the ratio of Si—C bonds in the third film can be made larger than the ratio of Si—C bonds in the first film, and the ratio of C—H bonds in the third film can be made smaller than the ratio of C—H bonds in the first film. In this way, at least the surface of the third film can be made highly dense. By setting the ratio of Si—C bonds to C—H bonds in the third film as described above, it is possible to improve the ashing resistance of the third film (SiOC film). Further, by increasing the density of at least the surface of the third film, it is possible to improve the ashing resistance of the third film (SiOC film). By performing the plasma processing to the second film under the above-described processing conditions, it is possible to allow the modified third film to have good ashing resistance while maintaining a low dielectric constant.

Further, under the above-described processing conditions, at least a part of Si, O, and C contained in the second film remains in the third film without being removed.

If the processing temperature is less than 100 degrees C., the third film (SiOC film) formed on the wafer 200 may not have good ashing resistance. By setting the processing temperature to 100 degrees C. or higher, it becomes possible to form a third film with excellent ashing resistance on the wafer 200. By setting the processing temperature to 450 degrees C. or higher, it becomes possible to form a third film with better ashing resistance on the wafer 200.

When the processing temperature exceeds 850 degrees C., a large amount of excited H atoms (H*) are generated, which may make it difficult to control the processing time and the like. By setting the processing temperature to 850 degrees C. or lower, an appropriate amount of H* can be generated, and the processing time and the like can be easily controlled. By setting the processing temperature to 600 degrees C. or lower, it is possible to easily generate an appropriate amount of H*, and it is possible to easily control the processing time and the like.

### (After-Purging and Atmospheric Pressure Restoration: S503)

After the plasma processing is completed, the gaseous substances remaining in the process chamber 501 are removed from the inside of the process chamber 501 using the same processing procedure and processing conditions as those for the above-described purging (after-purging). Thereafter, the atmosphere inside the process chamber 501 is replaced with the purge gas, and the pressure inside the process chamber 401 is returned to the atmospheric pressure (atmospheric pressure restoration).

### (Unloading the Wafer to the Outside of the Plasma-Processing Apparatus 500: S504)

Thereafter, the susceptor 510 is lowered to a predetermined transfer position, and the wafer 200 is delivered from the susceptor 510 onto the lift pins 507. Thereafter, the GV 1490c is opened, and the processed wafer 200 is unloaded to the outside of the process container 503 (TM 2400) by the vacuum transfer robot 2700. Thereafter, the processed wafer 200 is loaded into a predetermined pod 2001 in the reverse procedure of the wafer loading (S300) described above. Thus, the substrate-processing process according to the present embodiment is completed.

### (6) Effects of the Present Embodiment

According to the present embodiment, one or more of the following effects may be obtained.

(a) By performing steps a to c non-simultaneously in the order of steps a, b, and c, the third film (SiOC film) can be formed as a film having both a low dielectric constant and high ashing resistance. Specifically, in step b, by removing moisture and impurities from the first film, the second film can be formed as a low-k film with a low dielectric constant. Furthermore, in step c, by making the ratio of Si—C bonds to C—H bonds in the third film larger than the ratio of Si—C bonds to C—H bonds in the first film, the third film can be formed as a film having good ashing resistance and, ultimately, good HF resistance. In this way, the third film (SiOC film) can be formed as a film that achieves both a low dielectric constant and high processing resistance (ashing resistance (and HF resistance)).

(b) By setting the processing temperature in step c to a higher processing temperature than the processing temperature in step a, it is possible to reliably break the C—H bonds contained in the second film while the Si—C bonds contained in the second film are retained intact in the third film. As a result, the third film (SiOC film) can be reliably formed as a film having excellent ashing resistance.

In the substrate-processing process, if steps a and b are performed in this order without performing step c, it may not be possible to break the C—H bonds contained in the first film. As a result, it may not be possible to make the ratio of Si—C bonds to C—H bonds in the second film larger than the ratio of Si—C bonds to C—H bonds in the first film. Therefore, it may not be possible to form the modified SiOC film as a film having good ashing resistance.

In addition, in the substrate-processing process, if steps a and c are performed in this order without performing step b, in step c, the film may be cured while allowing the moisture and impurities present in the first film to remain. As a result, the modified SiOC film may not be formed as a film having a low dielectric constant (low-k film).

In addition, in the substrate-processing process, if steps a to c are performed in the order of steps a, c, and b, the modified SiOC film may not be formed as a film having good ashing resistance. Specifically, the SiOC film formed in step a contains, for example, OH groups (Si—OH bonds) in addition to C—H bonds and Si—C bonds on its surface, and the bonding state of the surface thereof is not constant. If step c is performed to a SiOC film whose surface is in such a state, the modified SiOC film may not be formed as a film having good ashing resistance. Even if step b is performed thereafter, there is a high possibility that the film cannot be modified into a film having good ashing resistance.

As described above, in the present embodiment, the above-mentioned effects can be obtained by performing steps a to c non-simultaneously in the order of steps a, b, and c.

### Other Embodiments of the Present Disclosure

The embodiment of the present disclosure has been specifically described above. However, the present disclosure is not limited to the above-described embodiment, and various changes can be made without departing from the gist thereof.

In the above-described embodiment, there has been described the example in which a film (SiOC film) containing C—H bonds and Si—C bonds is formed as the first film in step a. However, the present disclosure is not limited thereto. For example, a SiOCN film or a SiCN film containing N—H bonds and Si—N bonds may be formed as the first film.

In these cases, for example, a trichloroborane (BCl₃) gas may be used as the catalyst. As the precursor (gas), it may be possible to use, for example, a 1,4-disilabutane (SiH₃CH₂CH₂SiH₃, abbreviation: 1,4-DSB) gas, a trisilylamine (N(SiH₃)₃, abbreviation: TSA) gas, a BTCSM gas, a 1,1,3,3-tetrachloro-1,3-disilacyclobutane (C₂H₄Cl₄Si₂, abbreviation: TCDSCB) gas, a dichlorosilane (SiH₂Cl₂, abbreviation: DCS) gas, a 1,1,2,2-tetrachloro-1,2-dimethyldisilane ((CH₃)₂Si₂Cl₄, abbreviation: TCDMDS) gas, and a hexachlorodisilane (Si₂Cl₆, abbreviation: HCDS) gas. As the reaction gas, it may be possible to use, for example, an ammonia (NH₃) gas, an oxygen (O₂) gas, a propylene (C₃H₆) gas, and a triethylamine ((C₂H₅)₃N, abbreviation: TEA) gas. As described above, it is preferable to use gases containing Si and H and at least one selected from the group of C and N as the film-forming gases (the catalyst, the precursor, and the reaction gas). Using these gases, films may be formed on the wafer 200 by the film-forming sequences indicated below. As indicated below, a combination of a plurality of precursors and a plurality of reaction gases may be used.

$$\begin{matrix}( BC {1}_{3} \to 1,4- DSB \to TSA \to {O}_{2} ) \times n \to SiOCN \\ ( BTCSM \to {NH}_{3} \to {O}_{2} ) \times n \to SiOCN \\ ( TCDMDS \to {NH}_{3} ) \times n \to SiOCN \\ ( DCS \to {C}_{3} {H}_{6} \to {NH}_{3} ) \times n \to SiCN \\ ( TCDMDS \to {NH}_{3} ) \times n \to SiCN \\ ( HCDS \to TEA ) \times n \to SiCN\end{matrix}$$

The processing procedure and processing conditions when performing the substrate-processing sequences (steps a to c) including step a may be, for example, the same as the processing procedure and processing conditions in the above-described embodiment. Specifically, for example, step c is performed under conditions which are capable of retaining Si—N bonds and capable of breaking N—H bonds, and under conditions in which Si in the third film is bonded to N whose bond with H is broken. As a result, the ratio of Si—N bonds to N—H bonds in the third film can be made larger than the ratio of Si—N bonds to N—H bonds in the first film. Moreover, the ratio of Si—N bonds in the third film can be made larger than the ratio of Si—N bonds in the first film, and the ratio of N—H bonds in the third film can be made smaller than the ratio of N—H bonds in the first film. This makes it possible to obtain the same effects as those of the above-mentioned embodiment.

Further, as the precursor (gas), an inorganic chlorosilane-based gas such as a tetrachlorosilane (SiCl₄, abbreviation: STC) gas, an octachlorotrisilane (Si₃Cl₈, abbreviation: OCTS) gas, or the like may also be used. In addition, as the precursor, for example, a halogen-free organic silane precursor gas such as a dimethylsilane (SiC₂H₈, abbreviation: DMS) gas, a trimethylsilane (SiC₃H₁₀, abbreviation: TMS) gas, a diethylsilane (SiC₄H₁₂, abbreviation: DES) gas, or the like may also be used. Further, as the precursor, for example, a 1-monochloro-1,1,2,2,2-pentamethyldisilane ((CH₃)₅Si₂Cl, abbreviation: MCPMDS) gas, or the like may be used. In addition, as the precursor, an aminosilane-based gas such as a tetrakis(dimethylamino)silane (Si[N(CH₃)₂]₄, abbreviation: 4DMAS) gas, a tris(dimethylamino)silane (Si[N(CH₃)₂]₃H, abbreviation: 3DMAS)) gas, a bis(diethylamino)silane (Si[N(C₂H₅)₂]₂H₂, abbreviation: BDEAS) gas, a bis(tert-butylamino)silane (SiH₂[NH(C₄H₉)]₂, abbreviation):BTBAS) gas, a (diisopropylamino)silane (SiH₃[N(C₃H₇)₂], abbreviation: DIPAS) gas, or the like may also be used. One or more of these gases may be used as the precursor. In these cases, as well, it is possible to obtain the same effects as those of the above-described embodiments.

In the above-described embodiment, there has been described the example in which H₂ gas (hydrogen gas) is supplied to the wafer 200 in step c. However, the present disclosure is not limited thereto. For example, a plasma-processing gas containing at least one selected from the group of H, nitrogen (N), oxygen (O), and helium (He) may be supplied. Specifically, nitrogen plasma processing that supplies a N gas, nitrogen hydrogen plasma processing that supplies a N₂H₂ gas, oxygen hydrogen plasma processing that supplies an OH gas, oxygen plasma processing that supplies an O gas, and helium plasma processing that supplies a He gas may also be performed. In these cases, as well, it is possible to obtain the same effects as those of the above-described embodiment. However, the C—H bonds can be broken most efficiently when an H-containing gas is supplied and plasma-excited H (active species of H) is used. This is because the highly unstable hydrogen plasma reacts with the hydrogen in the C—H bond to become stable H₂. This is because hydrogen plasma easily reacts chemically with hydrogen.

In the above-described embodiment, there has been described the example using the single-substrate type apparatus that processes substrates one by one. However, the present disclosure is not limited thereto. For example, the present disclosure may be suitably applied even when using a batch-type substrate-processing apparatus that processes a plurality of substrates at a time. In this case, the three steps (steps a to c) may be performed in the same process chamber (in situ) within one apparatus. Even when such a substrate-processing apparatus is used, each process can be performed under the same processing procedure and processing conditions as in the above-described embodiment, and the same effects as in the above-described embodiment can be obtained.

Furthermore, in the above-described embodiment, there has been described the example in which three steps (steps a to c) are performed within one substrate-processing unit 2000. However, the present disclosure is not limited thereto. For example, the film-forming apparatus 300, the annealing apparatus 400, and the plasma-processing apparatus 500 may be configured as individual apparatuses, and in each apparatus, the corresponding process among the three processes (steps a to c) may be performed (ex situ).

In this specification, the above-described substrate-processing unit 2000, a single apparatus that performs three processes (steps a to c) in the same process chamber, and a group of apparatuses in which the film-forming apparatus 300, the annealing apparatus 400, and the plasma-processing apparatus 500 are configured as individual apparatuses are collectively referred to as a substrate processing system.

In the above-described embodiment, there has been described the example in which the SiOC film (first film) as a low-k film is formed in step a, and the heat processing is performed to the first film in step b. However, the present disclosure is not limited thereto. For example, instead of performing steps a and b, a wafer in which the low-k film formed on the surface has been heat-processed may be prepared, and step c may be performed to the wafer (low-k film). Also in this case, it is possible to obtain the same effects as in the above-described embodiment.

It is preferable that the recipes used for the respective processes are prepared individually according to the content of the processes and stored in the memory device 121c via a telecommunication line or the external memory device 123. Then, when starting each process, it is preferable that the CPU 121a appropriately selects an appropriate recipe from among the plurality of recipes stored in the memory device 121c according to the content of the process. This makes it possible to form films of various film types, composition ratios, film qualities, and film thicknesses with good reproducibility using one substrate-processing apparatus. Furthermore, the burden on an operator can be reduced, and each process can be started quickly while avoiding operational errors.

The above-mentioned recipe is not limited to being newly created, but may be prepared by, for example, changing an existing recipe that has already been installed in the substrate-processing apparatus. When changing a recipe, the changed recipe may be installed in the substrate-processing apparatus via a telecommunication line or a recording medium on which the recipe is recorded. Alternatively, the input/output device 122 provided in the existing substrate-processing apparatus may be operated to directly change an existing recipe already installed in the substrate-processing apparatus.

### Example

By performing the following substrate-processing sequences using the above-described substrate-processing apparatus, the SiOC film formed on the wafer was modified according to the film-forming sequence shown in FIG. 7, thereby producing Samples 1 and 2.

$$Sample 1 : ( precursor + catalyst \to oxidizing agent + catalyst ) \times n \to heat processing ( annealing processing ) \to SiOC film$$

$$Sample 2 : ( precursor + catalyst \to oxidizing agent + catalyst ) \times n \to heat processing ( annealing processing ) \to plasma ‐ excited {H}_{2} gas \to SiOC film$$

A BTCSM gas was used as the precursor (gas), an NH₃ gas was used as the catalyst, and a H₂O gas was used as the oxidizing agent. The processing conditions were predetermined conditions within the range of the processing conditions in each step shown in the above-described embodiment.

After producing Samples 1 and 2, the dielectric constant (k value) of each film of Samples 1 and 2 was measured. In addition, wet etching was performed on each film of samples 1 and 2 using a predetermined ashing apparatus, and then the wet etching rate (WER) when etching is performed using an aqueous hydrogen fluoride solution (DHF solution) diluted to 1% was measured.

As shown in FIG. 8, the dielectric constants (k values) of the films of Samples 1 and 2 were 3.5 and 4.2, respectively. It was confirmed that the films of Samples 1 and 2 have low dielectric constants. Furthermore, as shown in FIG. 8, it was confirmed that the WERs after the ashing process for the films of Samples 1 and 2 were more than 1000 Å/min and 16 Å/min, respectively. It was confirmed that the film of Sample 1 in which step c was not performed has a high WER after the ashing processing, i.e., poor ashing resistance. It was confirmed that the film of Sample 2 subjected to step c has a low WER after the ashing processing, i.e., good ashing resistance. From the above, it was confirmed that Sample 2 in which steps a to c were performed has a low dielectric constant and good ashing resistance. It was confirmed that Sample 1 in which step c was not performed has a low dielectric constant but has poor ashing resistance.

### Aspects of Present Disclosure

Hereinafter, some aspects of the present disclosure will be additionally described as supplementary notes.

### Supplementary Note 1

According to one aspect of the present disclosure, there is provided a method of manufacturing a semiconductor device or a method of processing a substrate, comprising:
(a) forming a low-k film on a substrate;
(b) performing heat processing to the low-k film; and
(c) performing plasma processing to the film subjected to (b) to remove H bonded to C or N in the film and to increase Si—C bonds or Si—N bonds to improve ashing resistance.

### Supplementary Note 2

According to another aspect of the present disclosure, there is provided a method of manufacturing a semiconductor device or a method of processing a substrate, comprising:
preparing a substrate having a surface on which a low-k film is formed and subjected to heat processing; and
performing plasma processing to the low-k film to make the ratio of Si—C bonds in the low-k film larger than the ratio of C—H bonds, or to make the ratio of Si—N bonds in the low-k film larger than the ratio of N—H bonds.

### Supplementary Note 3

According to a further aspect of the present disclosure, there is provided a method of manufacturing a semiconductor device or a method of processing a substrate, comprising:
(a) forming a film containing at least Si, C, H, and H₂O on a substrate;
(b) performing processing to the film formed in (a) to reduce moisture in the film; and
(c) removing H bonded to C or N in the film subjected to (b) to increase Si—C bonds or Si—N bonds to make at least the surface of the film highly dense to improve ashing resistance.

### Supplementary Note 4

According to a still further aspect of the present disclosure, there is provided a substrate processing system, a program, or a non-transitory computer-readable recording medium that records the program, which is configured to perform the method of any one of Supplementary Notes 1 to 3.

According to the present disclosure in some embodiments, it is possible to provide a technique capable of improving the properties of a film formed on a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) providing the substrate on which a first film containing at least one selected from the group of a combination of C—H bonds and Si—C bonds and a combination of N—H bonds and Si—N bonds is formed;
(b) modifying the first film into a second film by performing heat processing to the first film at a processing temperature higher than a processing temperature at which the first film is formed; and
(c) modifying the second film into a third film by performing plasma processing to the second film so that a ratio of Si—C bonds to C—H bonds in the third film is made larger than a ratio of Si—C bonds to C—H bonds in the first film, or a ratio of Si—N bonds to N—H bonds in the third film is made larger than a ratio of Si—N bonds to N—H bonds in the first film.

2. The method of claim 1, wherein a processing temperature in (c) is higher than the processing temperature at which the first film is formed.

3. The method of claim 2, wherein the processing temperature in (c) is lower than the processing temperature in (b).

4. The method of claim 1, wherein the first film contains C—H bonds and Si—C bonds, and
wherein (c) is performed under a condition that a ratio of Si—C bonds in the third film is larger than a ratio of Si—C bonds in the first film, and a ratio of C—H bonds in the third film is smaller than a ratio of C—H bonds in the first film.

5. The method of claim 1, wherein the first film contains C—H bonds and Si—C bonds, and
wherein (c) is performed under a condition in which C—H bonds are capable of being broken and Si in the third film is bonded to C whose bond with H is broken.

6. The method of claim 1, wherein the first film contains C—H bonds and Si—C bonds, and
wherein in (c), the second film is modified into the third film such that the ratio of Si—C bonds to C—H bonds in the third film is larger than the ratio of Si—C bonds to C—H bonds in the first film.

7. The method of claim 1, wherein the first film is formed by supplying a precursor containing at least C—H bonds and Si—C bonds to the substrate.

8. The method of claim 1, wherein the first film is formed by supplying a precursor containing at least C—H bonds and Si—C bonds and a catalyst to the substrate and supplying an oxidizing agent and a catalyst to the substrate alternately.

9. The method of claim 8, wherein the precursor is a chlorosilane-based gas.

10. The method of claim 1, wherein the first film, the second film, and the third film are films containing Si, O, and C.

11. The method of claim 1, wherein the first film is a film containing moisture, and wherein in (b), the moisture is removed from the first film.

12. The method of claim 1, wherein the first film contains N—H bonds and Si—N bonds, and
wherein (c) is performed under a condition that a ratio of Si—N bonds in the third film is larger than a ratio of Si—N bonds in the first film, and a ratio of N—H bonds in the third film is smaller than a ratio of N—H bonds in the first film.

13. The method of claim 1, wherein the first film contains N—H bonds and Si—N bonds, and
wherein (c) is performed under a condition that Si—N bonds are capable of being held and N—H bonds are capable of being broken.

14. The method of claim 1, wherein the first film contains N—H bonds and Si—N bonds, and
wherein (c) is performed under a condition in which N—H bonds are capable of being broken and Si in the third film is bonded to N whose bond with H is broken.

15. The method of claim 1, wherein the first film, the second film, and the third film are films containing Si, O, and N.

16. The method of claim 1, wherein in (c), a gas containing at least one selected from the group of H, N, O, and He is supplied to the substrate.

17. The method of claim 1, wherein (c) is performed at a temperature of 450 degrees C. or higher and 600 degrees C. or lower.

18. A method of manufacturing a semiconductor device, comprising:
the method of claim 1.

19. A non-transitory computer-readable recording medium storing a program that causes, by a computer, a substrate processing apparatus to perform a process comprising:
(a) providing a substrate on which a first film containing at least one selected from the group of a combination of C—H bonds and Si—C bonds and a combination of N—H bonds and Si—N bonds is formed;
(b) modifying the first film into a second film by heating the substrate to perform heat processing to the first film at a processing temperature higher than a processing temperature at which the first film is formed; and
(c) modifying the second film into a third film by supplying a plasma-processing gas excited into a plasma state to the substrate to perform plasma processing to the second film so that a ratio of Si—C bonds to C—H bonds in the third film is made larger than a ratio of Si—C bonds to C—H bonds in the first film, or a ratio of Si—N bonds to N—H bonds in the third film is made larger than a ratio of Si—N bonds to N—H bonds in the first film.

20. A substrate processing apparatus, comprising:
a film-forming gas supply system configured to supply a film-forming gas containing Si and H and at least one selected from the group of C and N to a substrate;
a heating mechanism configured to heat a substrate;
a plasma generator configured to excite a plasma-processing gas into a plasma state; and
a controller configured to be capable of controlling the heating mechanism and the plasma generator so as to perform a process including:
(a) providing the substrate on which a first film containing at least one selected from the group of a combination of C—H bonds and Si—C bonds and a combination of N—H bonds and Si—N bonds is formed;
(b) modifying the first film into a second film by heating the substrate to perform heat processing to the first film at a processing temperature higher than a processing temperature at which the first film is formed; and
(c) modifying the second film into a third film by supplying the plasma-processing gas excited into the plasma state to the substrate to perform plasma processing to the second film so that a ratio of Si—C bonds to C—H bonds in the third film is made larger than a ratio of Si—C bonds to C—H bonds in the first film, or a ratio of Si—N bonds to N—H bonds in the third film is made larger than a ratio of Si—N bonds to N—H bonds in the first film.
